(19) United States
(12) Patent Application Publication
(10) Pub. No.: US 2023/0183568 A1
(43) Pub. Date: Jun. 15, 2023

(54) METHOD OF PREPARING QUANTUM DOT, QUANTUM DOT PREPARED BY THE METHOD, OPTICAL MEMBER INCLUDING THE QUANTUM DOT, AND ELECTRONIC APPARATUS INCLUDING THE QUANTUM DOT

(71) Applicant: Samsung Display Co., Ltd., Yongin-si (KR)

(72) Inventors: Juo Nam, Yongin-si (KR); Jaebok Chang, Yongin-si (KR); Junehyuk Jung, Yongin-si (KR); Sungjae Kim, Yongin-si (KR); Donghee Lee, Yongin-si (KR); Taekjoon Lee, Yongin-si (KR)

(21) Appl. No.: 18/062,727

(22) Filed: Dec. 7, 2022

(30) Foreign Application Priority Data
Dec. 9, 2021 (KR) 10-2021-0176109

(51) Int. Cl. C09K 11/62; B82Y 20/00; C09K 11/64; H01L 33/50

(52) U.S. Cl. CPC C09K 11/62; B82Y 20/00; C09K 11/64; H01L 33/504; H01L 2933/0041

(57) ABSTRACT

Provided are: a method of preparing a quantum dot, the method including preparing a first particle including a Group III-V compound including gallium (Ga) and treating the first particle with an aluminum (Al) composition including an aluminum (Al) precursor; a quantum dot manufactured by the method; an optical member including the quantum dot; and an electronic apparatus including the quantum dot.

### CROSS-REFERENCE TO RELATED APPLICATION

This application claims priority to and the benefit of Korean Patent Application No. 10-2021-0176109, filed on Dec. 9, 2021, in the Korean Intellectual Property Office, the entire content of which is hereby incorporated by reference.

### BACKGROUND

### 1. Field

One or more embodiments of the present disclosure relate to a method of preparing a quantum dot, a quantum dot prepared by the method, an optical member including the quantum dot, and an electronic apparatus including the quantum dot.

### 2. Description of the Related Art

Quantum dots can be utilized as materials that perform various optical functions (for example, a light conversion function, a light emission function, and/or the like) in optical members and various electronic apparatuses. Quantum dots, which are semiconductor nanocrystals with a quantum confinement effect, may have different energy bandgaps by control of the size and composition of the nanocrystals, and thus may emit light of various emission wavelengths.

An optical member including such quantum dots may have the form of a thin film, for example, a thin film patterned for each subpixel. Such an optical member may be used as a color conversion member of a device including various light sources.

Quantum dots may be used for a variety of purposes in various electronic apparatuses. For example, quantum dots may be used as emitters. For example, quantum dots may be included in an emission layer of a light-emitting device including a pair of electrodes and the emission layer so as to act as an emitter.

Currently, to implement high-definition optical members and electronic apparatuses, there is a desire for the development of quantum dots that emit blue light having a maximum emission wavelength of 490 nm or less, that have high photoluminescence quantum yield (PLQY), and that do not include cadmium that is a toxic element.

### SUMMARY

One or more embodiments of the present disclosure relate to a method of preparing a quantum dot, a quantum dot prepared by the method, an optical member including the quantum dot, and an electronic apparatus including the quantum dot.

Additional aspects of embodiments will be set forth in part in the description which follows and, in part, will be apparent from the present description, or may be learned by practice of the presented embodiments of the present disclosure.

According to one or more embodiments, a method of preparing a quantum dot includes:
preparing a first particle including a Group III-V compound containing gallium (Ga); and
treating the first particle with an aluminum (Al) composition including an aluminum (Al) precursor.

According to one or more embodiments,
provided is a quantum dot which is prepared by the method, and
includes a first particle including a Group III-V compound containing gallium (Ga); and
an aluminum (Al) passivation layer surrounding the first particle.

According to one or more embodiments, an optical member includes the quantum dot.

According to one or more embodiments, an electronic apparatus includes the quantum dot.

### BRIEF DESCRIPTION OF THE DRAWINGS

The above and other aspects and features of certain embodiments of the disclosure will be more apparent from the following description taken in conjunction with the accompanying drawings, in which:

FIG. 1 shows a diagram schematically illustrating a cross-section of a quantum dot according to an embodiment; and

FIG. 2 shows a schematic view of an electronic apparatus according to an embodiment; and

FIG. 3 shows a schematic view of an electronic apparatus according to an embodiment.

### DETAILED DESCRIPTION

Reference will now be made in more detail to embodiments of the present disclosure, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The subject matter of the present disclosure may undergo various suitable transformation and have diverse modified embodiments. Accordingly, embodiments are illustrated in the drawings and are described in the detailed description. An effect and a characteristic of embodiments of the present disclosure, and a method of accomplishing these will be apparent when referring to embodiments described with reference to the drawings. The subject matter of the present disclosure may, however, be embodied in many different forms and should not be construed as limited to the embodiments set forth herein.

It will be understood that although the terms “first,” “second,” etc., as used herein, may describe various components, but these components should not be limited by these terms. These terms are only used to distinguish one component from another.

An expression used in the singular encompasses the expression of the plural, unless it has a clearly different meaning in the context.

The terms such as “including,” “having,” and “comprising,” as used herein, are intended to indicate the existence of the features or components disclosed in the specification, and are not intended to preclude the possibility that one or more other features or components may exist or may be added. For example, unless limited otherwise, terms such as “include” or “have” may refer to both the case of constituting only the features or components described in the specification and the case of further including other components.

The term “Group II,” as used herein, may include a Group llA element and a Group IIB element on the IUPAC periodic table, and the Group II element may include, for example, magnesium (Mg), calcium (Ca), zinc (Zn), cadmium (Cd), and mercury (Hg).

The term “Group III,” as used herein, may include a Group lllA element and a Group lllBelement on the IUPAC periodic table, and the Group lll include, for example, aluminum (Al), gallium (Ga), indium (In), and thallium (Tl).

The term “Group V,” as used herein, may include a Group VA element and a Group VB element on the IUPAC periodic table, and the Group V element may include, for example, nitrogen (N), phosphorus (P), arsenic (As), and antimony (Sb).

The term “Group VI,” as used herein, may include a Group VIA element and a Group VIB element on the IUPAC periodic table, and the Group VI element may include, for example, sulfur (S), selenium (Se), and tellurium (Te).

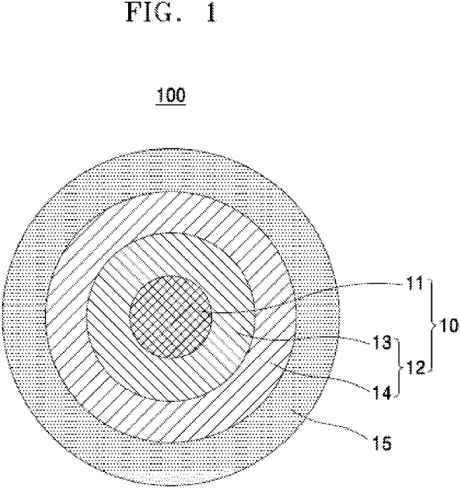

Hereinafter, embodiments of a quantum dot 100 and a method of preparing the same will be described with reference to FIG. 1.

According to an embodiment, provided is a method of preparing a quantum dot includes: preparing a first particle 10 including a Group III-V compound containing gallium (Ga); and treating the first particle 10 with an aluminum (Al) composition including an aluminum (Al) precursor.

In an embodiment, the preparing of the first particle 10 including the Group III-V compound containing gallium (Ga) may include forming a Group III-V compound containing gallium (Ga) from gallium (Ga) precursor, a Group III precursor, and a Group V precursor.

According to an embodiment, the forming of the Group III-V compound containing gallium (Ga) may be performed at a temperature of 120° C. to 280° C. For example, the forming of the Group III-V compound containing gallium (Ga) may be performed at a temperature of 150° C. to 250° C.

According to an embodiment, the gallium (Ga) precursor may include trimethyl gallium, triethyl gallium, gallium acetate, gallium oleate, gallium acetylacetonate, gallium-3-chloride, gallium fluoride, gallium oxide, gallium nitrate, gallium sulfate, or any combination thereof.

For example, the gallium (Ga) precursor may include gallium acetate, gallium oleate, gallium-3-chloride, gallium fluoride, or any combination thereof.

According to an embodiment, the Group III precursor may include a gallium precursor, an indium precursor, a thallium precursor, and any combination thereof. For example, the Group III precursor may include trimethyl gallium, triethyl gallium, gallium acetate, gallium oleate, gallium acetylacetonate, gallium-3-chloride, gallium fluoride, gallium oxide, gallium nitrate, gallium sulfate, indium acetylacetonate, trimethyl indium, indium acetate, indium hydroxide, indium chloride, indium oxide, indium nitrate, indium sulfate, thallium acetate, thallium acetylacetonate, thallium chloride, thallium oxide, thallium ethoxide, thallium nitrate, thallium sulfate, thallium carbonate, or any combination thereof. For example, the Group III precursor may not contain a gallium precursor.

For example, the Group III precursor may include an indium precursor or a thallium precursor. For example, the Group III precursor may include indium acetylacetonate, trimethyl indium, indium acetate, Indium hydroxide, indium chloride, indium oxide, indium nitrate, indium sulfate, thallium acetate, thallium acetylacetonate, thallium chloride, thallium oxide, thallium ethoxide, thallium nitrate, thallium sulfate, thallium carbonate, or any combination thereof.

For example, the Group III precursor may include an indium precursor. For example, the Group III precursor may include indium acetylacetonate, trimethyl indium, indium acetate, Indium hydroxide, indium chloride, indium oxide, indium nitrate, indium sulfate, or any combination thereof.

According to an embodiment, the Group V precursor may include a phosphine precursor, an arsenic precursor, or any combination thereof. For example, the Group V precursor may include tris trimethylsilyl phosphine, tris(dimethylamino) phosphine, triethyl phosphine, tributyl phosphine, trioctylphosphine, triphenyl phosphine, tricyclohexyl phosphine, arsenic oxide, arsenic chloride, arsenic sulfate, arsenic bromide, arsenic iodide, nitric oxide, nitric acid, ammonium nitrate, or any combination thereof.

For example, the Group V precursor may include a phosphine precursor. For example, the Group V precursor may include tris trimethylsilyl phosphine, tris (dimethylamino)phosphine, triethyl phosphine, tributyl phosphine, trioctylphosphine, triphenyl phosphine, tricyclohexyl phosphine, or any combination thereof.

According to an embodiment, the preparing of the first particle 10 including the Group III-V compound containing gallium (Ga) may include preparing a first mixture including a gallium (Ga) precursor, a Group III precursor, and a Group V precursor, and heating the first mixture.

For example, the heating of the first mixture may be performed at a temperature of 120° C. to 280° C. For example, the heating of the first mixture may be performed at a temperature of 150° C. to 250° C.

According to an embodiment, the preparing of the first particles including the Group III-V compound containing gallium (Ga) may include preparing the first particles from a Group III-V compound containing gallium (Ga), a first precursor including a first metal element, a second precursor including a metal element, a third precursor including a third element, and a fourth precursor including a fourth element, wherein the first precursor and the second precursor may be different from each other, and the third element and the third precursor may be different from each other.

According to an embodiment, the preparing of the first particles including the Group III-V compound containing gallium (Ga) may include: preparing a second mixture from a Group III-V compound containing gallium (Ga), a first precursor including a first metal element, a second precursor including a metal element, a third precursor including a third element, and a fourth precursor including a fourth element; and heating the second mixture, wherein the first precursor and the second precursor may be different from each other, and the third element and the third precursor may be different from each other.

According to an embodiment, the first precursor and the second precursor may each independently include dimethyl zinc, diethyl zinc, zinc acetate, zinc acetylacetonate, zinc oleate, zinc stearate, zinc iodide, zinc bromide, zinc chloride, zinc fluoride, zinc carbonate, zinc cyanide, zinc nitrate, zinc oxide, zinc peroxide, zinc perchlorate, zinc sulfate, or any combination thereof.

For example, the first precursor and the second precursor may each independently include zinc chloride, zinc acetate, zinc acetylacetonate, zinc oleate, zinc stearate, or any combination thereof.

In one or more embodiments, a molar ratio of the first precursor and the second precursor may satisfy a range of 99:1 to 51:49, a range of 95:5 to 60:40, or a range of 90:10 to 70:30.

In one or more embodiments, the third element and the fourth element may each independently be a Group VI element.

The third element may be Se, and the fourth element may be S.

According to an embodiment, the third precursor may include tributylphosphine-selenide (TBP-Se), trioctylphosphine-selenide (TOP-Se) or any combination thereof, and the fourth precursor may include tributylphosphine-sulfide (TBP-S), trioctylphosphine-sulfide (TOP-S), or any combination thereof.

For example, the third precursor may include trioctylphosphine-selenide (TOP-Se), and the fourth precursor may include trioctylphosphine-sulfide (TOP-S).

In one or more embodiments, a molar ratio of the third element and the fourth element may satisfy a range of 99:1 to 99:1, for example, a range of 80:20 to 20:80, a range of 75:25 to 25:75, or a range of 75:25 to 50:50.

According to an embodiment, the heating of the second mixture may be performed at 100° C. to 400° C.

For example, the heating the second mixture may be performed at 120° C. to 340° C.

According to an embodiment, the treating the first particle with an aluminum composition including an aluminum precursor may include forming an aluminum passivation layer on the surface of the first particle.

According to an embodiment, the forming the aluminum passivation layer may be performed at a temperature of 120° C. to 230° C. for 10 minutes to 3 hours. For example, the forming the aluminum passivation layer may be performed at a temperature of 150° C. to 220° C. for 30 minutes to 2 hours.

According to an embodiment, the amount of the aluminum (Al) precursor may be 0.1 mole to 5 moles based on 100 moles of the aluminum (Al) composition. According to an embodiment, the amount of the aluminum (Al) precursor may be 0.2 moles to 3 moles based on 100 moles of the aluminum (Al) composition. According to an embodiment, the amount of the aluminum (Al) precursor may be 0.5 moles to 2 moles based on 100 moles of the aluminum (Al) composition.

According to an embodiment, the aluminum precursor may be represented by Formula 1:

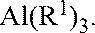

R¹ in Formula 1 may be deuterium, —F, —Cl, —Br, —I, a hydroxyl group, a cyano group, or a nitro group; and
a C₁-C₆₀ alkoxy group unsubstituted or substituted with at least one R₁₀ₐ.
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

For example, R¹ in Formula 1 may be deuterium, —F, —Cl, —Br, —I, a hydroxyl group, a cyano group, or a nitro group; or

a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, or any combination thereof.

For example, the aluminum precursor may include aluminum isopropyl oxide (Al(Oi-Pr)₃), aluminum chloride (Al(Cl)₃), aluminum bromide (Al(Br)₃), or any combination thereof.

In an embodiment, the aluminum composition may further include a solvent.

For example, the solvent may include a thiol-based solvent, an amine-based solvent, an alcohol-based solvent, or any combination thereof.

For example, the solvent may include an alkanethiol, a cycloalkanethiol, an alkane amine, a cycloalkane amine, an alkene amine, a cycloalkene amine, an alkyl alcohol, a cycloalkyl alcohol, or any combination thereof, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, or any combination thereof.

For example, the solvent may include dodecane thiol (DDT), chlorohexyl amine (CHA), oleylamine, octanol, or any combination thereof.

In an embodiment, the treating the first particle with the aluminum composition containing the aluminum precursor may include: preparing a third mixture containing the aluminum composition containing the aluminum precursor and the first particle; and heating the third mixture to form an aluminum passivation layer on the surface of the first particle.

In an embodiment, the heating the third mixture to form an aluminum passivation layer on the surface of the first particle may be performed at a temperature of 120° C. to 230° C. for 10 minutes to 3 hours. In an embodiment, the heating the third mixture to form an aluminum passivation layer on the surface of the first particle may be performed at a temperature of 150° C. to 220° C. for 30 minutes to 2 hours.

Other details on the method of preparing the quantum dot will be understood by a person skilled in the art with reference to examples described herein below.

According to an embodiment, provided is a quantum dot 100 including: a first particle 10 including a Group III-V compound including gallium (Ga) prepared according to the above-described quantum dot preparation method; and an aluminum (Al) passivation layer 15 surrounding the first particle 10.

In an embodiment, the quantum dot 100 has a core 11-shell 12 structure, the core 11 contains a Group III-V compound including gallium (Ga), and the shell 12 may include a first region 13 including the third element or the fourth element and a second region 14 including a fourth element.

In an embodiment, the first particle 10 has a core 11-shell 12 structure, the core 11 contains a Group III-V compound including gallium (Ga), and the shell 12 may include a first region 13 including the third element or the fourth element and a second region 14 including a fourth element. For example, the first particle 10 may be a quantum dot.

The shell 12 may be formed on the surface of the core 11 and may act as a protective layer to prevent or reduce chemical modification of the core 11 and to maintain semiconductor properties thereof and/or as a charging layer to impart electrophoretic properties to the quantum dot 100 layer.

In an embodiment, the Group III-V compound containing gallium (Ga) may include InGaP, InGaS₃, InGaSe₃, GaInNP, GaInNAs, GaInNSb, GaInPAs, GaInPSb, or any combination thereof, and the shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, or any combination thereof.

According to another embodiment, the Group III-V compound containing gallium (Ga) may be InGaP, the first region (e.g., the first region 13) may include ZnSeₓS₁₋ₓ (0 <x≤1), and the second region (e.g., the second region 14) may include ZnS.

For example, from among the Group III-V compound containing gallium (Ga) and compounds contained in the shell, a multi-element compound containing two or more elements may have constituting elements, each existing in uniform or nonuniform concentration inside a particle.

In an embodiment, the core 11 has a first exciton peak of 300 nm to 500 nm, a peak to valley (PV) value of 0.1 to 1.0, and a half width half maximum of 20 nm to 40 nm. In an embodiment, the Group III-V compound containing gallium (Ga) has a first exciton peak of 300 nm to 500 nm, a PV value of 0.1 to 1.0, and a half width half maximum of 20 nm to 40 nm.

In an embodiment, the ratio of the amount of gallium (Ga) to the amount of indium (In) contained in the Group III-V compound containing gallium (Ga), as measured through inductively coupled plasma spectrometer (ICP) component analysis, may be from 0.1 atm% to 2 atm%. For example, ICP may refer to inductively coupled plasma spectroscopy.

For example, ICP may be performed using ICP-OES (inductively coupled plasma - optical emission spectrometry, instrumentation available from Perkin Elmer), and the analysis conditions include a plasma gas of 12 L/min, an auxiliary gas of 0.2 L/min, and a nebulizer gas of 0.8 L/min, a radio frequency (RF) power of 1300 WATTS, a sample flow rate of 1.50 mL/min, and a radial view.

For example, the ratio of the amount of gallium (Ga) to the amount of indium (In) contained in the Group III-V compound containing gallium (Ga), as measured through ICP component analysis, may be 0.2 atm% to 2 atm%, 0.4 atm% to 2 atm%, 0.1 atm% to 1 atm%, or 0.1 atm% to 0.5 atm%.

According to an embodiment, the ratio of the amount of aluminum (Al) included in the aluminum (Al) passivation layer to the amount of indium (In) included in the Group III-V compound including gallium (Ga) may be 1 to 10 atm%, the ratio of the amount of aluminum (Al) included in the aluminum (Al) passivation layer to the amount of zinc (Zn) included in the shell may be 0.1 to 2 atm%, and the ratio of the amount of gallium (Ga) to the amount of indium (In) contained in the Group III-V compound including gallium (Ga) may be 0.1 to 5 atm%, wherein these ratios are measured through X-ray photoelectron spectroscopy (XPS) analysis.

For example, XPS analysis may be performed using NUMA-Q 2000 of the manufacturer SEQUENT in conditions as follows: X-ray: mono Al ka 1486.6 eV, 100 mm, take off angle=45°, and reference: C 1s (at low b.e.) =284.8 eV.

For example, the ratio of the amount of aluminum (Al) included in the aluminum (Al) passivation layer to the amount of indium (In) included in the Group III-V compound containing gallium (Ga), which is measured by XPS analysis, may be 2 atm% to 10 atm%, 4 atm% to 10 atm%, 5 atm% to 10 atm%, 2 atm% to 8 atm%, 2 atm% to 6 atm%, or 3 atm% to 8 atm%.

For example, the ratio of the amount of aluminum (Al) included in the aluminum (Al) passivation layer to the amount of zinc (Zn) included in the shell measured through XPS analysis may be 0.1 atm% to 1.5 atm%, 0.1 atm% to 1.0 atm%, 0.2 atm% to 2.0 atm%, 0.4 atm% to 2.0 atm%, 0.5 atm% to 2.0 atm%, or 0.5 atm% to 1.5 atm%.

For example, the ratio of the amount of gallium (Ga) to the amount of indium (In) contained in the Group III-V compound containing gallium (Ga) measured through XPS analysis may be 0.1 atm% to 5 atm%, 0.2 atm% to 5 atm%, 0.5 atm% to 5 atm%, 1 atm% to 5 atm%, 0.1 atm% to 4 atm%, 0.1 atm% to 2 atm%, or 0.1 atm% to 1 atm%.

In an embodiment, the diameter of the first particle 10 may be 5 nm to 10 nm, 5 nm to 9 nm, or 6 nm to 8 nm.

According to an embodiment, the diameter of the quantum dot 100 may be 6 nm and 12 nm, for example, 6 nm and 11 nm, or 7 nm and 10 nm.

According to an embodiment, the thickness of the aluminum (Al) passivation layer 15 may be 0.1 nm to 3 nm, 0.2 nm to 3 nm, 0.5 to 3 nm, 0.1 nm to 2 nm, or 0.1 nm to 2 nm.

According to an embodiment, the maximum emission wavelength of the photo luminescence (PL) spectrum of the quantum dot may be 500 nm to 540 nm, 510 nm to 540 nm, 520 nm to 540 nm, or 525 nm to 540 nm.

According to an embodiment, the PL spectrum of the quantum dot may have a full width at half maximum (FWHM) of 30 nm to 60 nm, 30 nm to 45 nm, 30 nm to 43 nm, 30 nm to 40 nm, or 30 nm to 38 nm. When the FWHM of the quantum dot satisfies the above ranges, color purity and color reproducibility may be improved. In addition, because the light emitted through the quantum dot is emitted in all directions (e.g., substantially all directions), a wide viewing angle may be improved.

In one or more embodiments, the shape of the quantum dot is not specifically limited, and may be any suitable one generally used in the art. For example, the quantum dot may be in the form of a spherical particle, a pyramidal particle, a multi-arm particle, a cubic nanoparticle, a nanotube particle, a nanowire particle, a nanofiber particle, or a nanoplate particle.

In the case of preparing a quantum dot by the method of preparing the quantum dot as described above, the Group III-V compound containing gallium (Ga), for example, a semiconductor compound containing InGaP may have increased stability due to the aluminum passivation layer, even when the crystallinity and interface uniformity are changed.

As the size of the quantum dots becomes uniform (e.g., substantially uniform), the full width at half maximum (FWHM) of the quantum dots becomes narrow, so that color purity may be significantly improved, and PLQY characteristics and EtOH retention ratio may be improved. Due to the inclusion of the quantum dot, an optical member and an electronic apparatus, each of which has high quality and improved lifespan characteristics, may be provided.

In one or more embodiments, the quantum dot may further include a compound other than the above-described composition.

For example, the quantum dot may further include, in the core and the shell, a Group II-VI compound, a Group III-VI compound, a Group III-V compound, a Group IV-VI compound, a Group IV element or compound, a Group I-III-VI compound, or a combination thereof.

The Group II-VI compound may be selected from a binary compound selected from CdS, CdSe, CdTe, ZnS, ZnSe, ZnTe, ZnO, HgS, HgSe, HgTe, MgSe, MgS, and any mixture thereof; a ternary compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any mixture thereof; and a quaternary compound selected from CdZnSeS, CdZnSeTe, CdZnSTe, CdHgSeS, CdHgSeTe, CdHgSTe, HgZnSeS, HgZnSeTe, HgZnSTe, and any mixture thereof.

The Group III-VI compound may include: a binary compound, such as In₂S₃ and/or In₂Se; a ternary compound, such as InGaS₃ and/or InGaSe₃; or any combination thereof.

For example, the Group III-V compound may be selected from: a binary compound selected from GaN, GaP, GaAs, GaSb, AIN, AIP, AlAs, AlSb, InN, InP, InAs, InSb, and any mixture thereof; a ternary compound selected from GaNP, GaNAs, GaNSb, GaPAs, GaPSb, AINP, AINAs, AINSb, AlPAs, AlPSb, InGaP, InAlP, InNP, InNAs, InNSb, InPAs, InPSb, GaAINP, and any mixture thereof; and a quaternary compound selected from GaAINAs, GaAINSb, GaAlPAs, GaAlPSb, GalnNP, GalnNAs, GalnNSb, GalnPAs, GalnPSb, InAINP, InAINAs, InAINSb, InAIPAs, InAIPSb, and any mixture thereof, but embodiments of the present disclosure are not limited thereto. The Group III-V compound may further include a Group II metal (for example, InZnP, and/or the like).

The IV-VI group compound may be selected from: a binary compound selected from SnS, SnSe, SnTe, PbS, PbSe, PbTe, and any mixture thereof; a ternary compound selected from SnSeS, SnSeTe, SnSTe, PbSeS, PbSeTe, PbSTe, SnPbS, SnPbSe, SnPbTe, and any mixture thereof; and a quaternary compound selected from SnPbSSe, SnPbSeTe, SnPbSTe, and any mixture thereof. The Group IV element may be selected from Si, Ge, and any mixture thereof. The Group IV compound may be a binary compound selected from SiC, SiGe, and any mixture thereof.

The Group I-III-VI semiconductor compound may include a ternary compound, such as AgInS, AgInS₂, CuInS, CuInS₂, CuGaO₂, AgGaO₂, and/or AgAlO₂; or any combination thereof.

The binary compound, the ternary compound, or the quaternary compound may exist in particles at uniform (e.g., substantially uniform) concentration, or may exist in the same particle in a state in which a concentration distribution is partially different.

In one or more embodiments, the shell may include a metal and/or non-metal oxide, a semiconductor compound, or a combination thereof.

For example, the metal and/or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄.

For example, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, and/or the like.

### Optical Member

The quantum dot may be used in various suitable optical members. According to another aspect of embodiments, provided is an optical member including the quantum dot.

In one or more embodiments, the optical member may be a light control means.

In one or more embodiments, the optical member may be a color filter, a color conversion member, a capping layer, a light-extraction efficiency enhancement layer, a selective light-absorption layer, and/or a polarizing layer.

For example, the optical member may be a color conversion member.

### Apparatus

The quantum dot may be used in various suitable electronic apparatuses. According to another aspect of embodiments, provided is an electronic apparatus including the quantum dot.

According to an embodiment, provided is an electronic apparatus including: a light source, and a color conversion member in an optical path of light emitted from the light source, wherein the color conversion member includes the quantum dot.

FIG. 2 is a schematic view showing a structure of an electronic apparatus 200A according to an embodiment. The electronic apparatus 200A of FIG. 2 includes a substrate 210, a light source on the substrate 210, and a color conversion member 230 on the light source 220.

For example, the light source 220 may be a backlight unit (BLU) for use in liquid crystal displays (LCD), a fluorescent lamp, a light-emitting device, an organic light-emitting device, or a quantum-dot light-emitting device (QLED), or any combination thereof. The color conversion member 230 may be in at least one direction of travel of light emitted from the light source 220.

At least a region of the color conversion member 230 of the electronic apparatus 200A includes the quantum dot, and the region absorbs light emitted from the light source to emit blue light having a maximum light-emitting wavelength in a range of about 510 nm to about 540 nm.

The wording that the color conversion member 230 is in at least one direction in which the light emitted from the light source 220 travels, does not exclude other elements from being further included between the color conversion member 230 and the light source 220.

For example, between the light source 220 and the color conversion member 230, a polarizing plate, a liquid crystal layer, a light guide plate, a diffusion plate, a prism sheet, a microlens sheet, a luminance enhancing sheet, a reflective film, a color filter, or any combination thereof may be additionally arranged.

In other embodiments, a polarizing plate, a liquid crystal layer, a light guide plate, a diffusion plate, a prism sheet, a microlens sheet, a luminance enhancing sheet, a reflective film, a color filter, or any combination thereof may be additionally on the color conversion member 230.

The electronic apparatus 200A illustrated in FIG. 2, which is an embodiment according to the disclosure, and may have any of various suitable shapes, and accordingly, may further include various suitable structures.

In other embodiments, the electronic apparatus may include a structure including a light source, a light guide plate, a color conversion member, a first polarizing plate, a liquid crystal layer, a color filter, and a second polarizing plate that are sequentially arranged.

In still other embodiments, the electronic apparatus may include a structure including a light source, a light guide plate, a first polarizing plate, a liquid crystal layer, a second polarizing plate, and a color conversion member that are sequentially arranged.

In the embodiments described above, the color filter may include a pigment and/or a dye. In the embodiments described above, one selected from the first polarizing plate and the second polarizing plate may be a vertical polarizing plate, and the other one may be a horizontal polarizing plate.

In other embodiments, the quantum dot as described in the present specification may be used as an emitter. According to another embodiment, provided is an electronic apparatus including a light-emitting device that includes: a first electrode; a second electrode facing the first electrode; and an emission layer between the first electrode and the second electrode, wherein the light-emitting device (for example, the emission layer of the light-emitting device) includes the quantum dot. The light-emitting device may further include a hole transport region between the first electrode and the emission layer, an electron transport region between the emission layer and the second electrode, or a combination thereof.

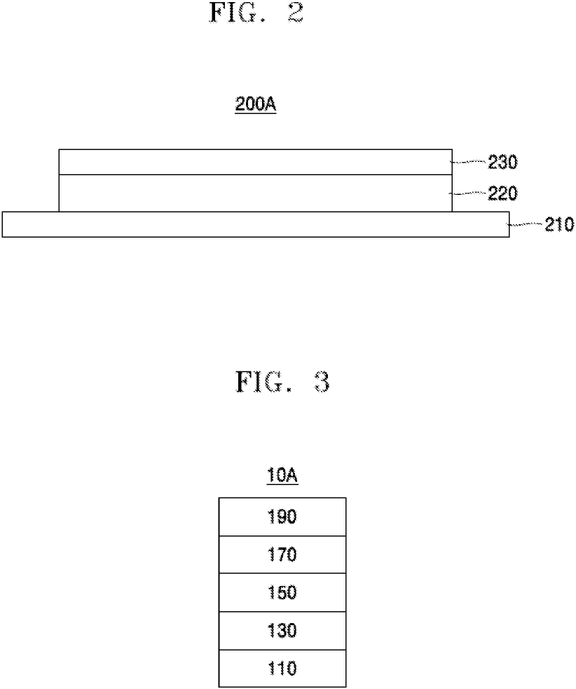

FIG. 3 is a schematic cross-sectional view showing a structure of a light-emitting device 10A according to an embodiment.

The light-emitting device 10A includes: a first electrode 110; a second electrode 190 facing the first electrode 110; an emission layer 150 that is between the first electrode 110 and the second electrode 190 and includes the quantum dot; a hole transport region between the first electrode 110 and the emission layer 150; and an electron transport region 170 between the emission layer 150 and the second electrode 190. Hereinafter, the layers of the light-emitting device 10A will be further described.

### First Electrode 110

A substrate may be additionally under the first electrode 110 and/or above the second electrode 190. The substrate may be a glass substrate and/or a plastic substrate, each having excellent mechanical strength, thermal stability, transparency, surface smoothness, ease of handling, and water resistance.

For example, when the light-emitting device 10A is a top-emission type (or kind) in which light is emitted in the opposite direction of the substrate, the substrate may not be essentially transparent, and may be opaque or semi-transparent. In this case, the substrate may be formed of metal. When the substrate is formed of metal, the substrate may include carbon, iron, chromium, manganese, nickel, titanium, molybdenum, stainless steel (SUS), an Invar alloy, an Inconel alloy, a Kovar alloy, or any combination thereof.

In some embodiments, a buffer layer, a thin-film transistor, an organic insulating layer, and/or the like may be further included between the substrate and the first electrode 110.

The first electrode 110 may be formed by, for example, depositing and/or sputtering a material for forming the first electrode 110 on the substrate. The first electrode 110 may be a reflective electrode, a semi-transmissive electrode, or a transmissive electrode. To form the first electrode 100 which is a transmission-type (or kind) electrode, the material for the first electrode may include indium tin oxide (ITO), indium zinc oxide (IZO), tin oxide (SnO₂), zinc oxide (ZnO), gallium zinc oxide (GZO), aluminum zinc oxide (AZO), InZnSnOₓ (IZSO), ZnSnOₓ (ZSO), graphene, PEDOT:PSS, carbon nanotubes, silver (Ag) nanowire, gold (Au) nanowire, metal mesh, or any combination thereof. In one or more embodiments, when the first electrode 110 is a semi-transmissive electrode or a reflective electrode, a material for forming a first electrode may include magnesium (Mg), silver (Ag), aluminum (Al), aluminum-lithium (Al-Li), calcium (Ca), magnesium-indium (Mg—In), magnesium-silver (Mg—Ag), or any combinations thereof.

The first electrode 110 may have a single-layered structure or a multi-layered structure including two or more layers. For example, the first electrode 110 may have a three-layered structure of ITO/Ag/ITO.

### Hole Transport Region 130

The hole transport region 130 may have: i) a single-layered structure consisting of a single layer consisting of a single material; ii) a single-layered structure consisting of a single layer consisting of a plurality of different materials; or iii) a multi-layered structure including a plurality of layers including different materials.

The hole transport region 130 may include a hole injection layer, a hole transport layer, an emission auxiliary layer, an electron-blocking layer, or any combination thereof.

For example, the hole transport region 130 may have a single-layered structure including a single layer including a plurality of different materials, or a multi-layered structure of a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, the constituent layers of each structure being stacked sequentially from the first electrode 110 in the stated order.

The hole transport region 130 may include an amorphous inorganic material and/or organic material. The inorganic material may include NiO, MoO₃, Cr₂O₃, and/or Bi₂O₃. The inorganic material may include a p-type inorganic semiconductor, for example, a p-type inorganic semiconductor in which an iodide, bromide, and/or chloride of Cu, Ag and/or Au is doped with non-metal such as O, S, Se and/or Te; a p-type inorganic semiconductor in which a Zn-containing compound is doped with metal, such as Cu, Ag, and/or Au, and non-metal, such as N, P, As, Sb and/or Bi; and/or an intrinsic p-type inorganic semiconductor such as ZnTe.

The organic material may include m-MTDATA, TDATA, 2-TNATA, NPB (NPD), β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate (PANI/PSS), polyvinylcarbazole (PVK), a compound represented by Formula 201, a compound represented by Formula 202, or any combination thereof:

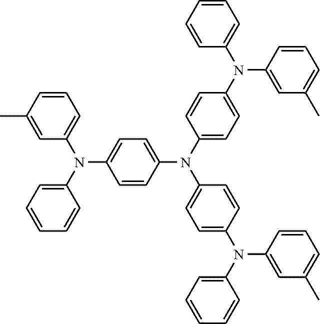

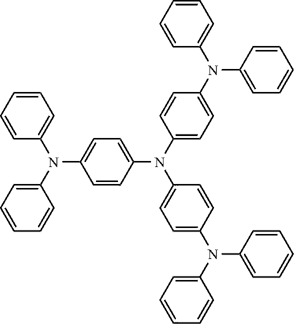

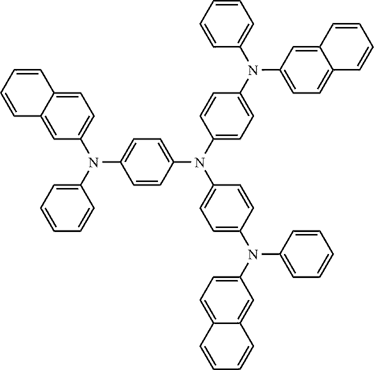

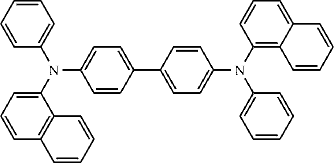

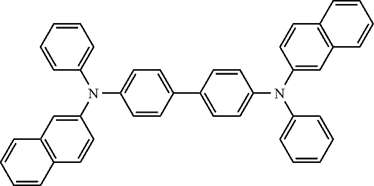

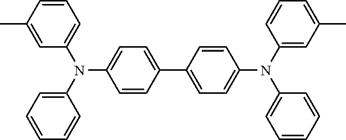

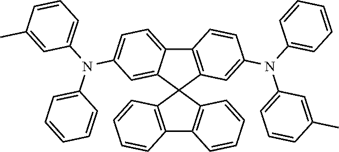

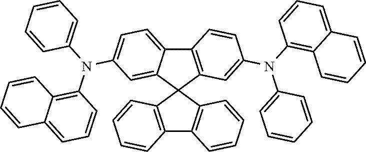

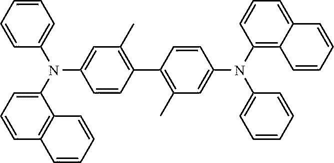

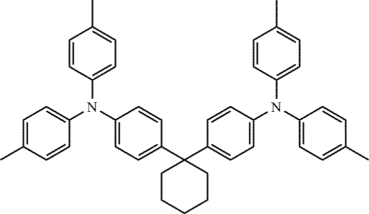

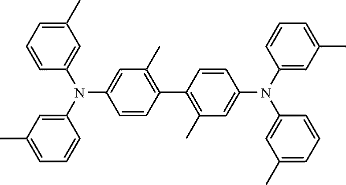

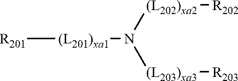

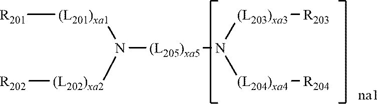

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,
R₂₀₁ and R₂₀₂ may optionally be linked to each other, via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ (for example, a carbazole group),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

The hole transport region 130 may have a thickness of about 50 Å to about 10000 Å, for example, about 100 Å to about 4000 Å. When the hole transport region 130 includes a hole injection layer, a hole transport layer, or any combination thereof, a thickness of the hole injection layer may be in a range of about 100 Å to about 9,000 Å, for example, about 100 Å to about 1,000 Å, and a thickness of the hole-transporting layer may be in a range of about 50 Å to about 2,000 Å, for example, about 100 Å to about 1,500 Å. When the thicknesses of the hole transport region 130, the hole injection layer, and the hole-transporting layer are within these ranges, suitable or satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron-blocking layer may block or reduce the leakage of electrons from the emission layer to the hole transport region 130. Materials that may be included in the hole transport region 130 may be included in the emission auxiliary layer and the electron-blocking layer.

### P-Dopant

The hole transport region 130 may further include, in addition to the materials as described above, a charge-generation material for the improvement of conductive characteristics (e.g., electrically conductive characteristics). The charge-generation material may be uniformly or non-uniformly dispersed in the hole transport region 130 (for example, in the form of a single layer consisting of a charge generation material).

The charge-generation material may be, for example, a p-dopant.

For example, the lowest unoccupied molecular orbital (LUMO) energy level of the p-dopant may be -3.5 eV or less.

In one or more embodiments, the p-dopant may include a quinone derivative, a cyano group-containing compound, a compound including element EL1 and element EL2, or any combination thereof.

Examples of the quinone derivative are TCNQ, F4-TCNQ, etc.

Examples of the cyano group-containing compound are HAT-CN, and a compound represented by Formula 221 below.

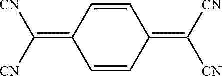 [SMILES: N#CC(C#N)=c1ccc(=C(C#N)C#N)cc1]

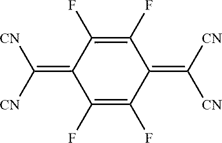 [SMILES: N#CC(C#N)=c1c(F)c(F)c(=C(C#N)C#N)c(F)c1F]

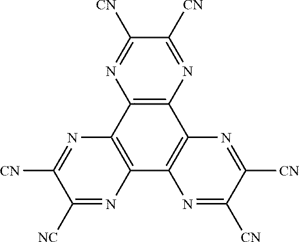

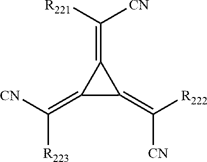

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal include an alkali metal (for example, lithium (Li), sodium (Na), potassium (K), rubidium (Rb), cesium (Cs), etc.); alkaline earth metal (for example, beryllium (Be), magnesium (Mg), calcium (Ca), strontium (Sr), barium (Ba), etc.); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); post-transition metal (for example, zinc (Zn), indium (In), tin (Sn), etc.); and lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid include silicon (Si), antimony (Sb), and tellurium (Te).

Examples of the non-metal include oxygen (O) and halogen (for example, F, Cl, Br, I, etc.).

Examples of the compound including element EL1 and element EL2 include metal oxide, metal halide (for example, metal fluoride, metal chloride, metal bromide, and/or metal iodide), metalloid halide (for example, metalloid fluoride, metalloid chloride, metalloid bromide, and/or metalloid iodide), metal telluride, or any combination thereof.

Examples of the metal oxide include tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), and rhenium oxide (for example, ReO₃, etc.).

Examples of the metal halide include alkali metal halide, alkaline earth metal halide, transition metal halide, post-transition metal halide, and lanthanide metal halide.

Examples of the alkali metal halide include LiF, NaF, KF, RbF, CsF, LiCI, NaCl, KCI, RbCI, CsCI, LiBr, NaBr, KBr, RbBr, CsBr, Lil, Nal, Kl, Rbl, and Csl.

Examples of the alkaline earth metal halide include BeF₂, MgF₂, CaF₂, SrF₂, BaF₂, BeCl2, MgCl2, CaCl2, SrCl2, BaCl2, BeBr₂, MgBr₂, CaBr₂, SrBr₂, BaBr₂, BeI₂, MgI₂, CaI₂, SrI₂, and BaI₂

Examples of the transition metal halide include titanium halide (for example, TiF₄, TiCl₄, TiBr₄, TiI₄, etc.), zirconium halide (for example, ZrF₄, ZrCl₄, ZrBr₄, ZrI₄, etc.), hafnium halide (for example, HfF₄, HfCl₄, HfBr₄, HfI₄, etc.), vanadium halide (for example, VF₃, VCI₃, VBr₃, VI₃, etc.), niobium halide (for example, NbF₃, NbCl₃, NbBr₃, NbI₃, etc.), tantalum halide (for example, TaF₃, TaCl₃, TaBr₃, TaI₃, etc.), chromium halide (for example, CrF₃, CrCl₃, CrBr₃, CrI3, etc.), molybdenum halide (for example, MoF₃, MoCl₃, MoBr₃, MoI₃, etc.), tungsten halide (for example, WF₃, WCl₃, WBr₃, Wl₃, etc.), manganese halide (for example, MnF₂, MnCl₂, MnBr₂, MnI₂, etc.), technetium halide (for example, TcF₂, TcCl₂, TcBr₂, TcI₂, etc.), rhenium halide (for example, ReF₂, ReCl₂, ReBr₂, ReI₂, etc.), iron halide (for example, FeF₂, FeCl₂, FeBr₂, FeI₂, etc.), ruthenium halide (for example, RuF₂, RuCl₂, RuBr₂, RuI₂, etc.), osmium halide (for example, OsF₂, OsCl₂, OsBr₂, OsI₂, etc.), cobalt halide (for example, CoF₂, CoCl₂, CoBr₂, CoI₂, etc.), rhodium halide (for example, RhF₂, RhCl₂, RhBr₂, RhI₂, etc.), iridium halide (for example, IrF₂, IrCl₂, IrBr₂, IrI₂, etc.), nickel halide (for example, NiF₂, NiCl₂, NiBr₂, NiI₂, etc.), palladium halide (for example, PdF₂, PdCl2, PdBr₂, PdI₂, etc.), platinum halide (for example, PtF₂, PtCl₂, PtBr₂, PtI₂, etc.), copper halide (for example, CuF, CuCl, CuBr, CuI, etc.), silver halide (for example, AgF, AgCl, AgBr, AgI, etc.), and gold halide (for example, AuF, AuCI, AuBr, Aul, etc.).

Examples of the post-transition metal halide include zinc halide (for example, ZnF₂, ZnCl₂, ZnBr₂, ZnI₂, etc.), indium halide (for example, InI₃, etc.), and tin halide (for example, SnI₂, etc.).

Examples of the lanthanide metal halide include YbF, YbF₂, YbF₃, SmF₃, YbCl, YbCl₂, YbCl₃ SmCl₃, YbBr, YbBr₂, YbBr₃ SmBr₃, Ybl, YbI₂, YbI₃, and SmI₃

An example of the metalloid halide includes antimony halide (for example, SbCl₅, etc.).

Examples of the metal telluride include alkali metal telluride (for example, Li₂Te, a Na₂Te, K₂Te, Rb₂Te, Cs₂Te, etc.), alkaline earth metal telluride (for example, BeTe, MgTe, CaTe, SrTe, BaTe, etc.), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (for example, ZnTe, etc.), and lanthanide metal telluride (for example, LaTe, CeTe, PrTe, NdTe, PmTe, EuTe, GdTe, TbTe, DyTe, HoTe, ErTe, TmTe, YbTe, LuTe, etc.).

### Emission Layer 150

The emission layer 150 may be a quantum-dot single layer or a structure in which two or more quantum-dot layers are stacked. For example, the emission layer 150 may be a quantum-dot single layer or a structure in which 2 to 100 quantum-dot layers are stacked.

The emission layer 150 may include the quantum dot as described in the present specification.

The emission layer 150 may further include, in addition to the quantum dot as described in the present specification, a dispersion medium in which the quantum dot is dispersed in a naturally coordinated form. The dispersion medium may include an organic solvent, a polymer resin, or any combination thereof. The dispersion medium may be any suitable transparent medium that does not (or substantially does not) affect the optical performance of the quantum dot, is not (or is not substantially) deteriorated by light, does not (or substantially does not) reflect light, or does not (or substantially does not) absorb light. For example, the solvent may include toluene, chloroform, ethanol, octane, or any combination thereof, and the polymer resin may include epoxy resin, silicone resin, polystyrene resin, acrylate resin, or any combination thereof.

The emission layer 150 may be formed by coating, on the hole transport region 130, a quantum dot-containing composition for forming the emission layer, and volatilizing a portion or more of the solvent from the composition for forming the emission layer.

For example, as the solvent, water, hexane, chloroform, toluene, octane, and/or the like may be used.

The coating of the composition for forming the emission layer may be performed using a spin coat method, a casting method, a micro gravure coating method, a gravure coating method, a bar coating method, a roll coating method, a wire bar coating method, a dip coating method, a spray coating method, a screen printing method, a flexographic method, an offset printing method, an ink jet printing method, and/or the like.

When the light-emitting device 10A is a full-color light-emitting device, the emission layer 150 may include emission layers that emit light of different colors according to individual subpixels.

For example, the emission layer 150 may be patterned into a first-color emission layer, a second-color emission layer, and a third-color emission layer according to individual subpixels. Here, at least one emission layer of the emission layers described above may essentially include the quantum dot. For example, the first-color emission layer may be a quantum-dot emission layer including the quantum dot, and the second-color emission layer and the third-color emission layer may be organic emission layers including organic compounds, respectively. In this regard, the first color through the third color are different colors, and for example, the first color through the third color may have different maximum luminescence wavelengths. The first color through the third color may be white when combined together with each other.

In other embodiments, the emission layer 150 may further include a fourth-color emission layer, and at least one emission layer of the first-color to third-color emission layers may be a quantum-dot emission layer including the quantum dot, and the remaining emission layers may be organic emission layers including organic compounds, respectively. Other various suitable modifications are possible. In this regard, the first color through the fourth color are different colors, and for example, the first color through the fourth color may have different maximum luminescence wavelengths. The first color through the fourth color may be white when combined together with each other.

In an embodiment, the light-emitting device 10A may have a stacked structure in which two or more emission layers that emit light of identical or different colors contact (e.g., physically contact) each other or are spaced apart from each other. At least one emission layer of the at least two emission layers may be a quantum dot emission layer including the quantum dots, and the other emission layer may be an organic emission layer including organic compounds. Such a variation may be made. For example, the light-emitting device 10A may include a first-color emission layer and a second-color emission layer, and the first color and the second color may be the same color or different colors. In an embodiment, the first color and the second color may be both blue.

The emission layer 150 may further include, in addition to the quantum dot, at least one selected from among an organic compound and a semiconductor compound.

In more detail, the organic compound may include a host and a dopant. The host and the dopant may include any suitable host and any suitable dopant that are generally used in organic light-emitting devices, respectively.

In some embodiments, the semiconductor compound may be an organic and/or inorganic perovskite.

### Electron Transport Region 170

The electron transport region may have: i) a single-layered structure consisting of a single layer consisting of a single material, ii) a single-layered structure consisting of a single layer consisting of a plurality of different materials, or iii) a multi-layered structure including a plurality of layers including different materials.

The electron transport region 170 may include at least one layer selected from among a buffer layer, a hole-blocking layer, an electron control layer, an electron transport layer, and an electron injection layer. However, embodiments of the present disclosure are not limited thereto.

For example, the electron transport region 170 may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, the constituent layers of each structure being stacked sequentially from the emission layer. However, embodiments are not limited thereto.

The electron transport region 170 may include a conductive metal oxide. For example, ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof may be included.

The organic material may include any suitable compound having electron transport capability. In some embodiments, the organic material may include 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), NTAZ, and/or the like:

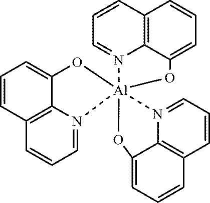

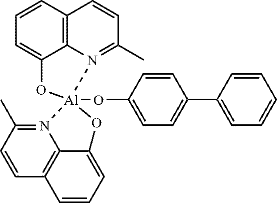

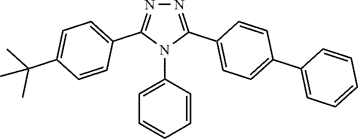 [SMILES: CC(C)(C)c1ccc(-c2nnc(-c3ccc(-c4ccccc4)cc3)n2-c2ccccc2)cc1]

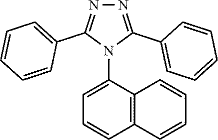 [SMILES: c1ccc(-c2nnc(-c3ccccc3)n2-c2cccc3ccccc23)cc1]

The organic material may be a metal-free compound including at least one Π electron-deficient nitrogen-containing C₁-C₆₀ cyclic group.

For example, the electron transport region 170 may include a compound represented by Formula 601:

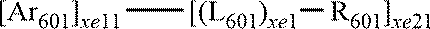

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be the same as described herein with respect to Q₁,
xe21 may be 1, 2, 3, 4, or 5,
at least one selected from Ar₆₀₁, L₆₀₁, and R₆₀₁ may each independently be a Π electron-deficient nitrogen-containing C₁-C₆₀ cyclic group unsubstituted or substituted with at least one R₁₀ₐ.

The electron transport region 170 may have a thickness of about 160 Å to about 5000 Å, for example, about 00 Å to about 4000 Å. When the electron transport region 170 includes a buffer layer, a hole-blocking layer, an electron control layer, an electron transport layer, or any combination thereof, a thickness of the buffer layer, the hole-blocking layer, or the electron control layer may each independently be from about 20 Å to about 1000 Å, for example, about 30 Å to about 300 Å, and a thickness of the electron transport layer may be from about 100 Å to about 1000 Å, for example, about 150 Å to about 500 Å. When the thickness of the buffer layer, the hole-blocking layer, the electron control layer, the electron transport layer, and/or the electron transport layer are within these ranges, suitable or satisfactory electron transporting characteristics may be obtained without a substantial increase in driving voltage.

The electron transport region 170 (for example, the electron transport layer in the electron transport region) may further include, in addition to the materials described above, a metal-containing material.

The metal-containing material may include an alkali metal complex, an alkaline earth metal complex, or any combination thereof. The metal ion of an alkali metal complex may be a Li ion, a Na ion, a K ion, a Rb ion, and/or a Cs ion, and the metal ion of an alkaline earth metal complex may be a Be ion, a Mg ion, a Ca ion, a Sr ion, and/or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) and/or ET-D2:

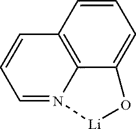

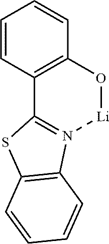

The electron transport region 170 may include an electron injection layer that facilitates the injection of electrons from the second electrode 190. The electron injection layer may directly contact (e.g., physically contact) the second electrode 190.

The electron injection layer may have: i) a single-layered structure consisting of a single layer consisting of a single material, ii) a single-layered structure consisting of a single layer consisting of a plurality of different materials, or iii) a multi-layered structure including a plurality of layers including different materials.

The electron injection layer may include an alkali metal, alkaline earth metal, a rare earth metal, an alkali metal-containing compound, alkaline earth metal-containing compound, a rare earth metal-containing compound, an alkali metal complex, an alkaline earth metal complex, a rare earth metal complex, or any combination thereof.

The alkali metal may include Li, a Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (for example, fluorides, chlorides, bromides, and/or iodides), and/or tellurides of the alkali metal, the alkaline earth metal, and the rare earth metal, or any combination thereof.

The alkali metal-containing compound may include: alkali metal oxides, such as Li₂O, Cs₂O, and/or K₂O; alkali metal halides, such as LiF, NaF, CsF, KF, Lil, Nal, Csl, and/or KI; or any combination thereof. The alkaline earth metal-containing compound may include an alkaline earth metal compound, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, Ybl₃, Scl₃, Tbl₃, or any combination thereof. In one or more embodiments, the rare earth metal-containing compound may include lanthanide metal telluride. Examples of the lanthanide metal telluride include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one selected from ions of the alkali metal, the alkaline earth metal, and the rare earth metal and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may include (e.g., consist of): i) an alkali metal-containing compound (for example, an alkali metal halide); or ii) a) an alkali metal-containing compound (for example, an alkali metal halide), and b) an alkali metal, an alkaline earth metal, a rare earth metal, or any combination thereof. For example, the electron injection layer may be a KI:Yb co-deposited layer, an Rbl:Yb co-deposited layer, and/or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å, and, for example, about 3 Å to about 90 Å. When the thickness of the electron injection layer is within the ranges described above, suitable or satisfactory electron injection characteristics may be obtained without a substantial increase in driving voltage.

### Second Electrode 190

The second electrode 190 is on an upper surface of the electron transport region 170 as described above. The second electrode 190 may be a cathode, which is an electron injection electrode, and as the material for the second electrode 190, a metal, an alloy, an electrically conductive compound, or any combination thereof, each having a low work function, may be used.

The second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 190 may be a transmissive electrode, a semi-transmissive electrode, or a reflective electrode.

The second electrode 190 may have a single-layered structure or a multi-layered structure including two or more layers.

The electronic apparatus (for example, a light-emitting apparatus) may further include, in addition to the light-emitting device 10A, i) a color filter, ii) a color conversion layer, or iii) a color filter and a color conversion layer. The color filter and/or the color conversion layer may be in at least one direction of travel of light emitted from the light-emitting device 10A. For example, light emitted from the light-emitting device 10A may be blue light or white light. For more details on the light-emitting device 10A, related descriptions provided above may be referred to. In one or more embodiments, the color conversion layer may include a quantum dot. The quantum dot may be, for example, a quantum dot as described herein.

The electronic apparatus may further include a thin-film transistor, in addition to the light-emitting device 10A as described above. The thin-film transistor may include a source electrode, a drain electrode, and an activation layer, and any one selected from the source electrode and the drain electrode may be electrically connected to one selected from the first electrode 110 and the second electrode 190 of the light-emitting device 10A.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion that seals the light-emitting device 10A. The sealing portion may be between the color filter and/or color conversion layer and the light-emitting device 10A. The sealing portion allows light from the light-emitting device 10A to be extracted to the outside, and concurrently (e.g., simultaneously) prevents or reduces penetration of ambient air and/or moisture into the light-emitting device 10. The sealing portion may be a sealing substrate including a transparent glass substrate and/or a plastic substrate. The sealing portion may be a thin-film encapsulation layer including at least one layer of an organic layer and/or an inorganic layer. When the sealing portion is a thin film encapsulation layer, the electronic apparatus may be flexible.

Various suitable functional layers may be additionally on the sealing portion, in addition to the color filter and/or the color conversion layer, according to the use of the electronic apparatus. Examples of the functional layers may include a touch screen layer, a polarizing layer, and the like. The touch screen layer may be a pressure-sensitive touch screen layer, a capacitive touch screen layer, and/or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the organic light-emitting device 10A, a biometric information collector.

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various suitable measuring instruments, meters (for example, meters for a vehicle, an aircraft, and/or a vessel), projectors, and/or the like.

### Definition of Terms

The term “C₃-C₆₀ carbocyclic group,” as used herein, refers to a cyclic group consisting of carbon only as a ring-forming atom and having three to sixty carbon atoms, and the term “C₁-C₆₀ heterocyclic group,” as used herein, refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed together with each other. For example, the C₁-C₆₀ heterocyclic group has 3 to 61 ring-forming atoms.

The term “cyclic group,” as used herein, may include the C₃-C₆₀ carbocyclic group, and the C₁-C₆₀ heterocyclic group.

The term “π electron-rich C₃-C₆₀ cyclic group,” as used herein, refers to a cyclic group that has three to sixty carbon atoms and does not include *—N═*′ as a ring-forming moiety, and the term “π electron-deficient nitrogen-containing C₁-C₆₀ cyclic group,” as used herein, refers to a heterocyclic group that has one to sixty carbon atoms and includes *—N═*′ as a ring-forming moiety.

For example,
the C₃-C₆₀ carbocyclic group may be i) group T1 or ii) a condensed cyclic group in which two or more groups T1 are condensed together with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) group T2, ii) a condensed cyclic group in which two or more groups T2 are condensed together with each other, or iii) a condensed cyclic group in which at least one group T2 and at least one group T1 are condensed together with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the π electron-rich C₃-C₆₀ cyclic group may be i) group T1, ii) a condensed cyclic group in which two or more groups T1 are condensed together with each other, iii) group T3, iv) a condensed cyclic group in which two or more groups T3 are condensed together with each other, or v) a condensed cyclic group in which at least one group T3 and at least one group T1 are condensed together with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),
the π electron-deficient nitrogen-containing C₁-C₆₀ cyclic group may be i) group T4, ii) a condensed cyclic group in which two or more groups T4 are condensed together with each other, iii) a condensed cyclic group in which at least one group T4 and at least one group T1 are condensed together with each other, iv) a condensed cyclic group in which at least one group T4 and at least one group T3 are condensed together with each other, or v) a condensed cyclic group in which at least one group T4, at least one group T1, and at least one group T3 are condensed together with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,
group T2 may be a furan group, a thiophene group, a 1 H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
group T3 may be a furan group, a thiophene group, a 1 H-pyrrole group, a silole group, or a borole group, and
group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group,” “the π electron-rich C₃-C₆₀ cyclic group,” or “the π electron-deficient nitrogen-containing C₁-C₆₀ cyclic group,” as used herein, refer to a group condensed to any cyclic group, a monovalent group, or a polyvalent group (for example, a divalent group, a trivalent group, a tetravalent group, etc.) according to the structure of a formula for which the corresponding term is used. For example, the “benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the monovalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group,” as used herein, refers to a linear or branched aliphatic hydrocarbon monovalent group that has one to sixty carbon atoms, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group,” as used herein, refers to a divalent group having substantially the same structure as the C₁-C₆₀ alkyl group.

The term “C₂-C₆₀ alkenyl group,” as used herein, refers to a monovalent hydrocarbon group having at least one carbon-carbon double bond at a main chain (e.g., in the middle) or at a terminal end (e.g., the terminus) of the C₂-C₆₀ alkyl group, and examples thereof include an ethenyl group, a propenyl group, and a butenyl group. The term “C₂-C₆₀ alkenylene group,” as used herein, refers to a divalent group having substantially the same structure as the C₂-C₆₀ alkenyl group.

The term “C₂-C₆₀ alkynyl group,” as used herein, refers to a monovalent hydrocarbon group having at least one carbon-carbon triple bond at a main chain (e.g., in the middle) or at a terminal end (e.g., the terminus) of the C₂-C₆₀ alkyl group, and examples thereof include an ethynyl group, and a propynyl group. The term “C₂-C₆₀ alkynylene group,” as used herein, refers to a divalent group having substantially the same structure as the C₂-C₆₀ alkynyl group.

The term “C₁-C₆₀ alkoxy group,” as used herein, refers to a monovalent group represented by -OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group,” as used herein, refers to a monovalent saturated hydrocarbon cyclic group having 3 to 10 carbon atoms, and examples thereof include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group,” as used herein, refers to a divalent group having substantially the same structure as the C₃-C₁₀ cycloalkyl group.

The term “C₁-C₁₀ heterocycloalkyl group,” as used herein, refers to a monovalent cyclic group of 1 to 10 carbon atoms, further including, in addition to carbon atoms, at least one heteroatom, as ring-forming atoms, and examples thereof include a 1,2,3,4-oxatriazolidinyl group, a tetrahydrofuranyl group, and a tetrahydrothiophenyl group. The term “C₁-C₁₀ heterocycloalkylene group,” as used herein, refers to a divalent group having substantially the same structure as the C₁-C₁₀ heterocycloalkyl group.

The term “C₃-C₁₀ cycloalkenyl group,” as used herein, refers to a monovalent cyclic group that has three to ten carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group,” as used herein, refers to a divalent group having substantially the same structure as the C₃-C₁₀ cycloalkenyl group.

The term “C₁-C₁₀ heterocycloalkenyl group,” as used herein, refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group,” as used herein, refers to a divalent group having substantially the same structure as the C₁-C₁₀ heterocycloalkenyl group.

The term “C₆-C₆₀ aryl group,” as used herein, refers to a monovalent group having a carbocyclic aromatic system of 6 to 60 carbon atoms, and the term “C₆-C₆₀ arylene group,” as used herein, refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed together with each other.

The term “C₁-C₆₀ heteroaryl group,” as used herein, refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group,” as used herein, refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed together with each other.

The term “monovalent non-aromatic condensed polycyclic group,” as used herein, refers to a monovalent group (for example, having 8 to 60 carbon atoms) having two or more rings condensed to each other, only carbon atoms as ring-forming atoms, and no aromaticity in its entire molecular structure (e.g., is not aromatic when considered as a whole). Examples of the monovalent non-aromatic condensed polycyclic group are an indenyl group, a fluorenyl group, a spiro-bifluorenyl group, a benzofluorenyl group, an indenophenanthrenyl group, and an indeno anthracenyl group. The term “divalent non-aromatic condensed polycyclic group,” as used herein, refers to a divalent group having substantially the same structure as the monovalent non-aromatic condensed polycyclic group described above.

The term “monovalent non-aromatic condensed heteropolycyclic group,” as used herein, refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure (e.g., is not aromatic when considered as a whole). Examples of the monovalent non-aromatic condensed heteropolycyclic group include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group,” as used herein, refers to a divalent group having substantially the same structure as the monovalent non-aromatic condensed heteropolycyclic group described above.

The term “C₆-C₆₀ aryloxy group,” as used herein, indicates —OA₁₀₂ (wherein A₁₀₂ is a C₆-C₆₀ aryl group), and the term “C₆-C₆₀ arylthio group,” as used herein, indicates —SA₁₀₃ (wherein A₁₀₃ is a C₆-C₆₀ aryl group).

The term “C₇-C₆₀ aryl alkyl group,” as used herein, refers to —A₁₀₄A₁₀₅ (where A₁₀₄ may be a C₁-C₅₄ alkylene group, and A₁₀₅ may be a C₆-C₅₉ aryl group), and the term “C₂-C₆₀ heteroaryl alkyl group,” as used herein, refers to —A₁₀₆A₁₀₇ (where A₁₀₆ may be a C₁-C₅₉ alkylene group, and A₁₀₇ may be a C₁-C₅₉ heteroaryl group).

The term “R₁₀ₐ,” as used herein, refers to:
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃ and Q₃₁ to Q₃₃ used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ aryl alkyl group; or a C₂-C₆₀ heteroaryl alkyl group.

The term “heteroatom,” as used herein, refers to any atom other than a carbon atom. Examples of the heteroatom are O, S, N, P, Si, B, Ge, Se, and any combinations thereof.

The term “third-row transition metal,” as used herein, includes hafnium (Hf), tantalum (Ta), tungsten (W), rhenium (Re), osmium (Os), iridium (Ir), platinum (Pt), gold (Au), and the like.

“Ph,” as used herein, refers to a phenyl group, “Me,” as used herein, refers to a methyl group, “Et,” as used herein, refers to an ethyl group, “ter-Bu” or “Bu^{t},” as used herein, refers to a tert-butyl group, and “OMe,” as used herein, refers to a methoxy group.

The term “biphenyl group,” as used herein, refers to “a phenyl group substituted with a phenyl group.” In other words, the “biphenyl group” is a substituted phenyl group having a C₆-C₆₀ aryl group as a substituent.

The term “terphenyl group,” as used herein, refers to “a phenyl group substituted with a biphenyl group”. In other words, the “terphenyl group” is a substituted phenyl group having, as a substituent, a C₆-C₆₀ aryl group substituted with a C₆-C₆₀ aryl group.

* and *′, as used herein, unless defined otherwise, each refer to a binding site to a neighboring atom in a corresponding formula or moiety.

Hereinafter, embodiments of the quantum dot preparation method and the quantum dot prepared according to the same will be described in more detail with reference to the following synthesis examples and examples.

### EXAMPLES

### Example 1

### Synthesis of Core

10 mmol indium acetate, 10 mmol Ga acetate, and 30 mmol fatty acid were mixed together in 200 ml solvent 1-octadecene, and then reacted at 120° C. to form a precursor. Then, 0.5 mmol sodium oleate and 5 mmol oleylamine were added thereto. After sufficient reaction, 12.5 mmol tris(trimethylsilyl)phosphine was added thereto and reacted at 250° C. to prepare a core.

The prepared InGaP Core had the 1^{st} exciton peak of 425 nm, the peak to valley was 0.8, and the half width half maximum was 31 nm.

### Synthesis of Shell

50 mmol zinc acetate and 100 mmol oleic acid were mixed together in 200 ml of solvent 1-octadecene and then reacted at 120° C. to form a precursor. Then, the InGaP core was dispersed in toluene and 0.4 mmol thereof was added. Thereafter, 55 mmol oleylamine and 6 mmol TOP-Se were added thereto, and were then reacted at 320° C. for 50 minutes. Then, 5.5 mmol ZnCl₂ and 7.5 mmol TOP-S were added thereto and additionally reacted to prepare a core-shell structure.

### Synthesis of Aluminum Passivation Layer

0.17 g (0.85 mmol) of Al(O-i-PR)₃ and 20 mL (83.5 mmol) of dodecane thiol (DDT) were reacted at a temperature of 60° C. for 1 hour to prepare an AI-DDT precursor.

7.5 mL of the AI-DDT precursor solution was further mixed together with 10 g of the InGaP solution (2.5 g of pure InGaP QD), and reacted at a temperature of 220° C. for 2 hours to prepare quantum dots.

### Examples 2 to 4 and Comparative Example 1

A quantum dot was prepared in substantially the same manner as in Example 1, except that the amount of Al(Oi-PR)₃, and the type (kind) and amount of the solvent were adjusted as shown in Table 1 below.

### Evaluation Example 1

In regard to the quantum dots prepared according to Examples 1 to 4 and Comparative Example 1, a spectrophotometer (QE-2100) was used in the condition of Optical Density 0.4 to measure photoluminescence quantum yield (PLQY) before purification, PLQY after purification, and EtOH retention ratio. Results thereof are shown in Table 1.

The purification of the quantum dot may be performed as follows: a first purification process was performed in such a manner that 30 ml of ethanol was added to 10 ml of quantum dot, and then centrifuging was performed at 9,000 rpm for 5 minutes, a second purification process was performed in such a manner that the first purified quantum dot was dissolved in 5 ml of toluene, and 15 ml of ethanol was added thereto, and then centrifuging was performed at 9,000 rpm for 5 minutes, a third purification process was performed in such a manner that the second purified quantum dot was dissolved in 5 ml of toluene, 15 ml of ethanol was added thereto, and then centrifuging was performed at 9,000 rpm for 5 minutes, and then, the second purified quantum dot was dissolved in 5 ml of toluene.

PLQY measurement before purification was performed in such a manner that 45 µl of quantum dot was added to 650 µl of toluene and the condition of Optical Density 0.4 was used, and PLQY measurement after purification was performed in such a manner that 25 µl of quantum dot was added to 650 µl of toluene and the condition of Optical Density 0.4 was used.

EtOH retention ratio was calculated through the following formula.

EtOH retention ratio = PLQY after purification / PLQY before purification

TABLE 1

| | Type of core | Amount of AI(O-i-PR)₃ | Type of solvent | Al/In | AI/Zn | PLQY before purification | PLQY after purification | EtOH retention ratio |
|---|---|---|---|---|---|---|---|---|
| Example 1 | InGaP | 0.86 mmol | dodecane thiol | 6.1 | 0.15 | 88.30% | 86.50% | 97.90% |
| Example 2 | InGaP | 2.55 mmol | dodecane thiol | 7.34 | 0.18 | 87.20% | 79.90% | 91.60% |
| Example 3 | InGaP | 4.25 mmol | dodecane thiol | 10.01 | 0.21 | 86.10% | 78.90% | 90.10% |
| Example 4 | InGaP | 2.55 mmol | cyclohexyl amine | 4.7 | 0.08 | 88.20% | 72.90% | 82.60% |
| Comparative Example 1 | InGaP | - | - | - | - | 88.80% | 72.10% | 81.20% |

Referring to Table 1, Examples 1 to 4 in which the aluminum passivation layer was formed showed increased PLQY and EtOH retention ratios compared to Comparative Example 1 in which the aluminum passivation layer was not formed. Accordingly, it can be seen that when the quantum dot included an aluminum passivation layer, the chemical and optical stability was improved.

As described above, quantum dots prepared using the quantum dot preparation method according to the embodiments exhibit a narrow FWHM and excellent color purity, and accordingly, the use of quantum dots provide a high-quality optical member and a high-quality electronic apparatus.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims, and equivalents thereof.

What is claimed is:

1. A method of preparing a quantum dot, the method comprising:
preparing a first particle comprising a Group III-V compound comprising gallium (Ga); and
treating the first particle with an aluminum (Al) composition comprising an aluminum (Al) precursor.

2. The method of claim 1, wherein the treating the first particle with the aluminum composition comprising the aluminum precursor comprises forming an aluminum passivation layer on a surface of the first particle.

3. The method of claim 2, wherein the forming the aluminum passivation layer is performed at a temperature of 120° C. to 230° C. for 10 minutes to 3 hours.

4. The method of claim 1, wherein an amount of the aluminum (Al) precursor is 0.5 moles to 2 moles based on 100 moles of the aluminum (Al) composition.

5. The method of claim 1, wherein the aluminum precursor is represented by Formula 1: 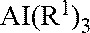
R¹ in Formula 1 is deuterium, —F, —Cl, —Br, —I, a hydroxyl group, a cyano group, or a nitro group; and
a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, or any combination thereof.

6. The method of claim 1, wherein the aluminum composition further comprises a solvent.

7. The method of claim 1, wherein the preparing of the first particle comprising the Group III-V compound comprising gallium (Ga) comprises forming the Group III-V compound comprising gallium (Ga) from a first mixture comprising a gallium (Ga) precursor, a Group III precursor, and a Group V precursor.

8. The method of claim 7, wherein the forming of the Group III-V compound comprising gallium (Ga) is performed at a temperature of 120° C. to 280° C.

9. The method of claim 1, wherein:
the preparing the first particle comprising the Group III-V compound comprising gallium (Ga) comprises: preparing a second mixture comprising a Group III-V compound comprising gallium (Ga), a first precursor comprising a first metal element, a second precursor comprising a second metal element, a third precursor comprising a third element, and a fourth precursor comprising a fourth element; and
heating the second mixture, wherein:
the first precursor and the second precursor are different from each other, and
the third element and the fourth element are different from each other.

10. The method of claim 9, wherein the heating of the second mixture is performed at a temperature of 100° C. to 400° C.

11. A quantum dot prepared by the method of claim 1, the quantum dot comprising:
a first particle comprising a Group III-V compound comprising gallium (Ga); and
an aluminum (Al) passivation layer surrounding the first particle.

12. The quantum dot of claim 11, wherein:
a maximum emission wavelength of a photo luminescence (PL) spectrum of the quantum dot is 500 nm to 540 nm, and
the PL spectrum of the quantum dot has a full width at half maximum (FWHM) of 30 nm to 60 nm.

13. The quantum dot of claim 11, wherein:
the quantum dot has a core-shell structure,
the core comprises a Group III-V compound comprising gallium (Ga), and
the shell comprises a first region comprising a third element or a fourth element and a second region comprising a fourth element.

14. The quantum dot of claim 13, wherein:
the Group III-V compound comprising gallium (Ga) is InGaP,
the first region comprises ZnSeₓS₁₋ₓ (wherein 0<x≤1), and
the second region comprises ZnS.

15. The quantum dot of claim 14, wherein a ratio of an amount of gallium (Ga) to an amount of indium (In) included in the Group III-V compound comprising gallium (Ga), as measured through inductively coupled plasma spectrometer (ICP) component analysis, is from 0.1 atm% to 2 atm%.

16. The quantum dot of claim 14, wherein a ratio of an amount of aluminum (Al) included in the aluminum (Al) passivation layer to the amount of indium (In) included in the Group III-V compound comprising gallium (Ga) is 1 atm% to 10 atm%, a ratio of an amount of aluminum (Al) included in the aluminum (Al) passivation layer to the amount of zinc (Zn) included in the shell is 0.1 atm% to 2 atm%, and a ratio of an amount of gallium (Ga) to an amount of indium (In) included in the Group III-V compound comprising gallium (Ga) is 0.1 atm% to 5 atm%, wherein each of the ratios is measured through X-ray photoelectron spectroscopy (XPS) analysis.

17. An optical member comprising the quantum dot of claim 11.

18. An electronic apparatus comprising the quantum dot of claim 11.

19. The electronic apparatus of claim 18, comprising:
a light source; and
a color conversion member in a path of light emitted from the light source,
wherein the quantum dot is included in the color conversion member.

20. The electronic apparatus of claim 18, comprising:
a light-emitting device comprising: a first electrode; a second electrode facing the first electrode; and an emission layer between the first electrode and the second electrode, wherein the quantum dot is included in the light-emitting device.
